(19) United States
(12) Patent Application Publication
(10) Pub. No.: US 2006/0226863 A1
(43) Pub. Date: Oct. 12, 2006

(54) Method and apparatus to adjust die frequency

(76) Inventors: Siva G. Narendra, Portland, OR (US); James W. Tschanz, Portland, OR (US); Victor Zia, Beaverton, OR (US); Badarinath Kommandur, Hillsboro, OR (US); Tawfik Arabi, Tigard, OR (US); Grant McFarland, Hillsboro, OR (US); Vivek K. De, Beaverton, OR (US)

Correspondence Address: FLESHNER-KIM, LLP;INTEL CORPORATION, P.O. BOX 221200, CHANTILLY, VA, 20153-1200, US

(21) Appl. No.: 11/094,574

(22) Filed: Mar. 31, 2005

(51) Int. Cl. G01R 31/26

(52) U.S. Cl. 324/765

(57) ABSTRACT

A method and apparatus are provided for adjusting a frequency of a die. This may include measuring characteristics of a die at various combinations of power supply voltage, body bias voltage and/or temperature and determining operating characteristics, such as power supply voltage and body bias voltage, based on the measured characteristics.

### FIELD

Embodiments of the present invention may relate to dies. More particularly, embodiments of the present invention may relate to adjusting frequencies of circuit elements on dies.

### BACKGROUND

Adaptive body bias techniques may be used after fabrication to improve a bin split in processors and to reduce a variation in frequency and leakage caused by process variations. In performing adaptive body bias, a unique body bias voltage may be set to maximize the frequency of the processor subject to leakage and total power constraints and the type of transistor technology in use. Body bias voltages may be applied to processors and other circuits that use P-type metal oxide semiconductor (PMOS) transistors, N-type metal oxide semiconductor (NMOS) transistors, or both.

Two types of body bias voltages may be used to control the frequency of a processor, namely forward body bias (FBB) voltages and reverse body bias (RBB) voltages. A forward body bias (FBB) voltage may reduce a threshold voltage of transistors, increase a drive current and increase circuit speed. At the same time, forward body bias may improve short-channel effects of the transistors. On the other hand, a reverse body bias (RBB) voltage may increase the threshold voltage, reduce the speed and also reduce the leakage current of the transistors. Body bias may therefore be used to control standby leakage of a processor while at a same time obtaining a maximum speed during active mode.

Adaptive power supply (V_{CC} or V_{dd}) techniques may also be used after fabrication. For example, for a part that requires a good deal of power, the supply voltage may be reduced, which reduces the leakage and lowers the overall frequency. Adaptive power supply techniques may be useful for reducing impacts of die-to-die and with-in parameter variations on frequency, active power and leakage power distributions of both low power and high performance processors.

### BRIEF DESCRIPTION OF THE DRAWINGS

The foregoing and a better understanding of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

The following represents brief descriptions of the drawings in which like reference numerals represent like elements and wherein:

FIG. 1 is a graph showing characteristics of adaptive techniques according to example arrangements;

FIG. 2 is a circuit diagram of an NMOS transistor using body bias to change a threshold voltage of the transistor according to an example arrangement;

FIG. 3 is a flowchart showing a technique of combining adaptive body bias with adaptive power supply for an NMOS transistor according to an example embodiment of the present invention;

FIG. 4 is a flowchart showing a technique of combining iso-reliability power supply with adaptive body bias for an NMOS transistor according to an example embodiment of the present invention;

FIG. 5 is a block diagram of a testing device according to an example embodiment of the present invention; and

FIG. 6 is a block diagram of a system according to an example embodiment of the present invention.

### DETAILED DESCRIPTION

In the following detailed description, like reference numerals and characters may be used to designate identical, corresponding or similar components in differing figure drawings. Further, in the detailed description to follow, example sizes/models/values/ranges may be given although the present invention is not limited to the same. Where specific details are set forth in order to describe example embodiments of the invention, it should be apparent to one skilled in the art that the invention can be practiced without these specific details.

In the following description, the terminology “supply voltage” and “voltage identification value” may be used. The supply voltage may be represented by V_{dd} and a voltage identification value may be represented by the symbol V_{ID}. The voltage identification value may be a value (or command) provided to a voltage regulator so as to provide an appropriate supply voltage (V_{dd}) to a die. Thus, there is a close correspondence between the supply voltage and the voltage identification value.

As stated above, frequency of a transistor or die may be adjusted based on an adaptive body bias technique or an adaptive power supply technique. Switching power (P_{SW}) of a transistor on a die is a function of the supply voltage. On the other hand, leakage power (Pₗₑₐₖ) is a function of both the threshold voltage (of a transistor on a die) as well as the supply voltage. The threshold voltage is a function of the body bias. Therefore, depending on leakage power or switching power, it may be better to use one adaptive technique rather than the other (i.e., adaptive body bias or adaptive power supply). In other words, both adaptive supply and adaptive body bias techniques impact the leakage power. Accordingly, embodiments of the present invention may combine adaptive body bias techniques and adaptive power supply techniques. This may reduce the impact of process variations. Further, the effectiveness of the combined scheme may improve with technology scaling due to increases in process variations.

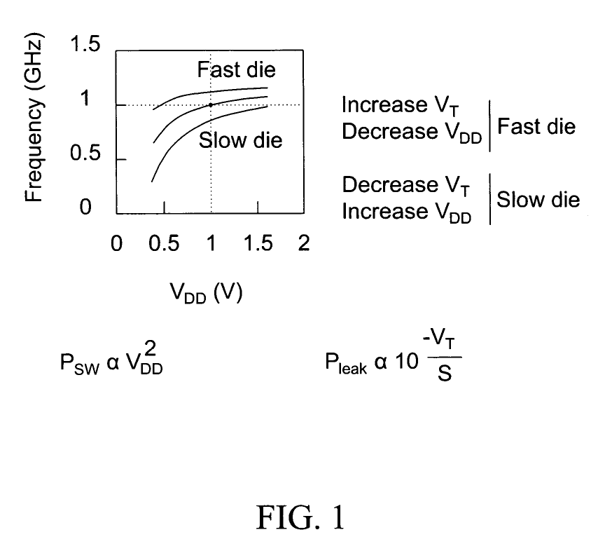

FIG. 1 is a graph showing characteristics of adaptive techniques according to example arrangements. Other graphs and arrangements are also possible. More specifically, FIG. 1 shows a concept of modulating a supply voltage (such as V_{dd}) and modulating a threshold voltage so as to increase or decrease a frequency of the die. Modulating the supply voltage (V_{dd}) may change a delay while impacting gate leakage, sub-threshold leakage, short circuit power and switching power. On the other hand, modulating the threshold voltage (V_{T}) may change the delay while impacting sub-threshold leakage and short circuit power.

FIG. 1 shows that a fast die (which has high power) can have its threshold voltage increased or its supply voltage reduced in order to reduce the power (which also reduces the frequency). On the other hand, FIG. 1 also shows that a slow die can have its threshold voltage decreased and its supply voltage increased in order to speed up the die.

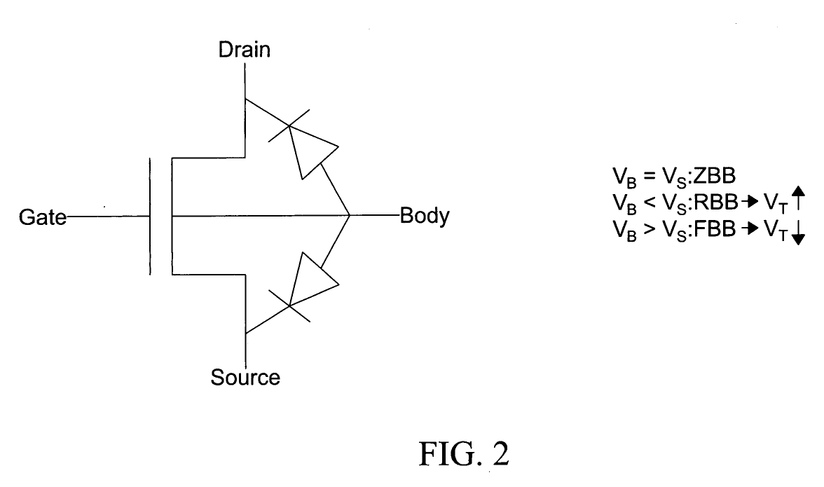

FIG. 2 is a circuit diagram of an NMOS transistor using a body bias technique to change a threshold voltage of the transistor of a die according to an example arrangement. Other arrangements are also possible. More specifically, FIG. 2 illustrates a concept of using body bias to modulate a threshold voltage. As shown, an NMOS transistor has a gate, a drain, a body and a source. When the voltage of the body (V_{B}) is equal to the voltage of the source (V_{S}), then the transistor has a zero body bias (ZBB). When the voltage of the body (V_{B}) is less than the voltage of the source (V_{S}), then the transistor has a reverse body bias (RBB). The reverse body bias of the NMOS transistor increases the threshold voltage of the transistor and accordingly decreases the speed of the transistor. On the other hand, when the voltage of the body (V_{B}) is greater than the voltage of the source (V_{S}), then the transistor has a forward body bias (FBB). The forward body bias of the NMOS transistor decreases the threshold voltage of the transistor and accordingly increases the speed of the transistor.

In adaptive power supply techniques, reducing the power supply may reduce the leakage and lower the overall frequency. On the other hand, increasing the power supply may increase the leakage and increase the overall frequency.

Embodiments of the present invention may combine features of adaptive body bias techniques and adaptive power supply (V_{dd}) techniques so as to improve and/or optimize the frequency of the transistors while maintaining power constraints. For example, a fast die may be brought under a power constraint by increasing a threshold voltage (Vₜ), reducing a supply voltage V_{dd} and/or using both techniques. Further, a slow die performance may be increased by reducing the threshold voltage Vₜ, increasing a supply voltage V_{dd} and/or using both techniques. Choosing a power supply value and a body bias value on a part-by-part basis may help choose a better power-frequency trade-off compared to choosing only the power supply voltage or the body bias. While embodiments of the present invention may be discussed with respect to optimized performance or frequency, embodiments of the present invention are also applicable to other performances or frequencies such as improved performance or frequency.

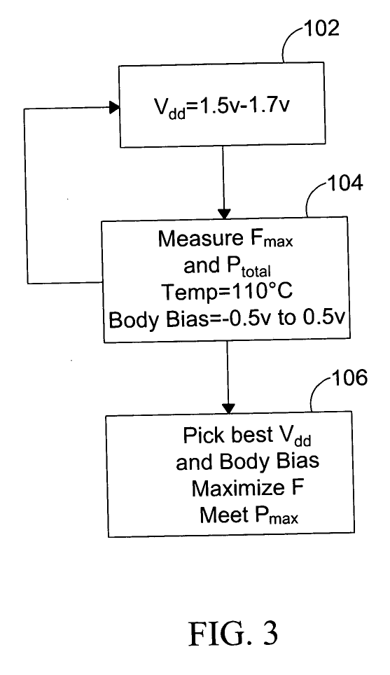

FIG. 3 is a flowchart showing a technique of combining adaptive body bias with adaptive power supply for an NMOS transistor according to an example embodiment of the present invention. Other operations, orders of operations, configurations and embodiments are also within the scope of the present invention. The technique shown in FIG. 3 may also be called an improved or optimized voltage identification technique as one example. The operations discussed in FIG. 3 may occur after fabrication and before distribution to customers. This technology may be utilized to set an ideal frequency of the transistors (or other parts) of the die. This technology may also be utilized to optimize or improve an operating frequency of the die.

More specifically, FIG. 3 shows that a supply voltage (V_{dd}) may be selected (or set) in block 102. This may be a value between 1.5 volts and 1.7 volts, for example. In block 104, various frequency and power measurements may be taken for different body bias voltages (such as −0.5 volts to 0.5 volts) applied to the die (or sample of dies) during the testing. The total power may be determined for each of these measurements (at specific supply voltages and body bias values) based on leakage and switching power. Alternatively, the total power may be determined (at specific supply voltages and body bias values) based on leakage depending on whether a whole wafer (or die) being tested is packaged or not. For example, in sort testing only leakage power may be measured. In class testing, the total switching and leakage power may be measured. Block 104 also shows that a specific temperature (such as 110° C., for example) may be maintained for the die during the testing. The data regarding the supply voltage, power, frequency and body bias voltage may be stored while operations are repeated for blocks 102 and 104 for different values (of the supply voltage and body bias). After determining various data based on the testing, operations may proceed to block 106. In block 106, an optimal (or improved) supply voltage and/or an optimal (or improved) body bias voltage may be selected based on the measured frequency and/or power so as to maximize a frequency of the die under test (or dies under test) and to meet any power requirements. Stated differently, block 106 involves a determination of the correlation of the data. These determined characteristics may be used to optimize or improve an operating frequency of the die. Block 106 is not limited to an optimized performance but may also include selecting a supply voltage and/or body bias voltage to improve a frequency of the die under test (and/or improve the operating frequency).

The operations of FIG. 3 may be performed after unsatisfactory dies have been discovered (and/or possibly removed from the wafer). After the appropriate supply voltage and body bias voltage are determined for a die (or dies), then these values may become the ideal values when the die is in actual use (such as after distribution to customers). For example, the supply voltage may thereafter be fixed for a particular die prior to its first use. This may allow ideal power and frequency performance. For example, a voltage identification value (V_{ID}) may be programmed and sent from a processor to a voltage regulator on the system so as to set an appropriate supply voltage V_{dd}. Embodiments of the present invention are not limited to ideal values as other values are also within the scope of the present invention.

Reliability is another issue for electronic components. Reliability is a function of both voltage and temperature. In certain arrangements, the supply voltage may be changed based on reliability constraints (and/or to make the reliability substantially constant). For example, if a die does not operate within parameter constraints, then the supply voltage may be lowered. However, the reliability of all parts (or dies) may be different from one another for any of a number of reasons. Temperature may be a factor with respect to performance (and reliability). For example, if the temperature of the die (or specific component of the die) increases, then the die may run at a lower frequency. On the other hand, if the temperature of the die (or specific component of the die) decreases, then the die may run at a higher frequency. As another example, if a transistor (or die) has lower leakage, then the transistor (or die) may run at a lower temperature and improve reliability. In order to run at a lower temperature, a higher supply voltage may be used to obtain the same reliability. It therefore is useful to know the supply voltage that may be used for various temperatures.

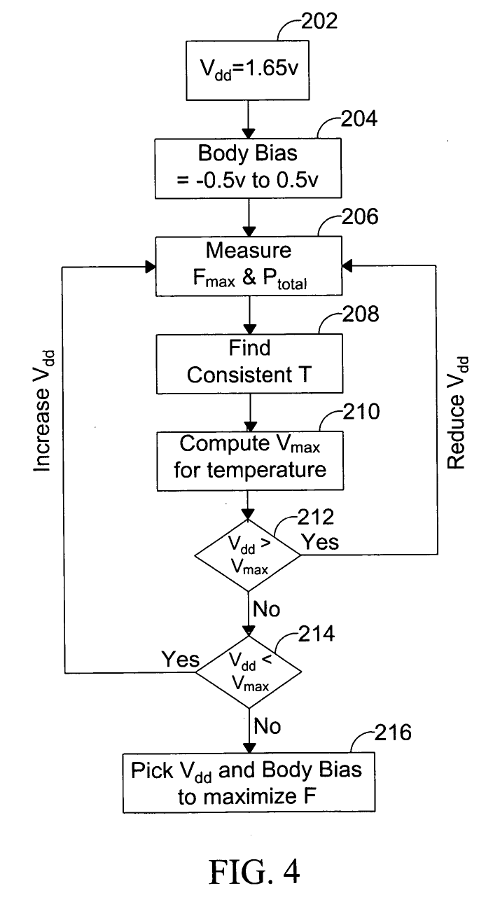

FIG. 4 is a flowchart showing a technique of combining iso-reliability power supply with adaptive body bias for an NMOS transistor according to an example embodiment of the present invention. Other operations, orders of operations, configurations and embodiments are also within the scope of the present invention. The technique shown in FIG. 4 may also be called optimized (or improved) temperature voltage identification as one example. Similar to FIG. 3, the operations discussed in FIG. 4 may occur after fabrication and before distribution to customers. This technology may be utilized to set an ideal frequency of the die (including the transistors and other parts). Embodiments of the present invention are not limited to optimized temperature voltage identification and/or ideal frequencies of the die. Embodiments may also include, for example, improved temperature voltage identification and/or improved frequencies of the die.

More specifically, FIG. 4 shows that a supply voltage may be selected (or set) in block 202. In this example, the supply voltage may be 1.65 volts, although other values are also within the scope of the present invention. In block 204, the body bias voltage may be selected to be a value between −0.5 volts and 0.5 volts. In block 206, the frequency and total power of the die (or sample of dies) may be measured. The temperature may be maintained at a certain value (or relatively constant temperature) as shown in block 208. This temperature may represent a maximum temperature expected for the die. This maximum temperature may be either directly measured or estimated using measurements of the die leakage and the operating frequency. A maximum supply voltage for the specific temperature may then be determined in block 210. In block 212, a determination is made whether the supply voltage is greater than the maximum voltage determined in block 210. If so, then the supply voltage may be decreased and operations return back to block 206. If not, then in block 214 a determination may be made whether the supply voltage is less than the maximum voltage determined in block 210. If so, then the supply voltage may be increased and operations return back to block 206. If the supply voltage is substantially identical to the maximum voltage determined in block 210, then the supply voltage is chosen in block 216 for the respective body bias voltage so as to maximize (or improve) the frequency of the die. Operations may then return to block 204 where another body bias voltage is selected. Operations in blocks 206, 208, 210, 212 and 214 may then be repeated until the supply voltage is chosen for the respective body bias voltage in block 216 so as to maximize (or improve) the frequency of the die (or the operating frequency of the die).

As may be seen in FIG. 4, when the supply voltage is changed and operations return to block 206 (after either blocks 212 or 214), then the frequency and total power may be measured again. The temperature may be maintained at a relatively constant temperature (i.e., a maximum expected temperature) in block 208 and a maximum (or improved) voltage may then be determined in block 210 for that respective temperature. This relatively constant temperature may be different than the relatively constant temperature previously maintained in block 208. Operations may then continue through blocks 212, 214 or 216 depending on the comparison between the supply voltage and the maximum voltage.

After determining various data based on the testing, an optimal (or improved) supply voltage and/or an optimal (or improved) body bias voltage may be selected based on the measured temperature, frequency and/or power so as to maximize a frequency of the die under test (or dies under test) and to meet any power requirements.

Arrangements and embodiments have been described above with respect to NMOS body bias and NMOS transistors. Embodiments of the present invention are also applicable to PMOS body bias and PMOS transistors. Using different body bias values for different sections of the die (i.e., within-die adaptive body bias) may be possible for PMOS transistors when n-well bulk process are used. Within-die adaptive body bias may also be possible for NMOS and PMOS transistors when triple-well bulk process are used.

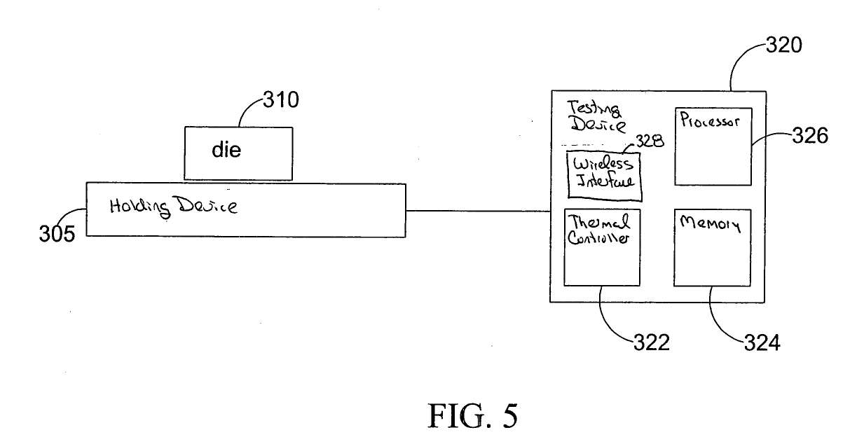

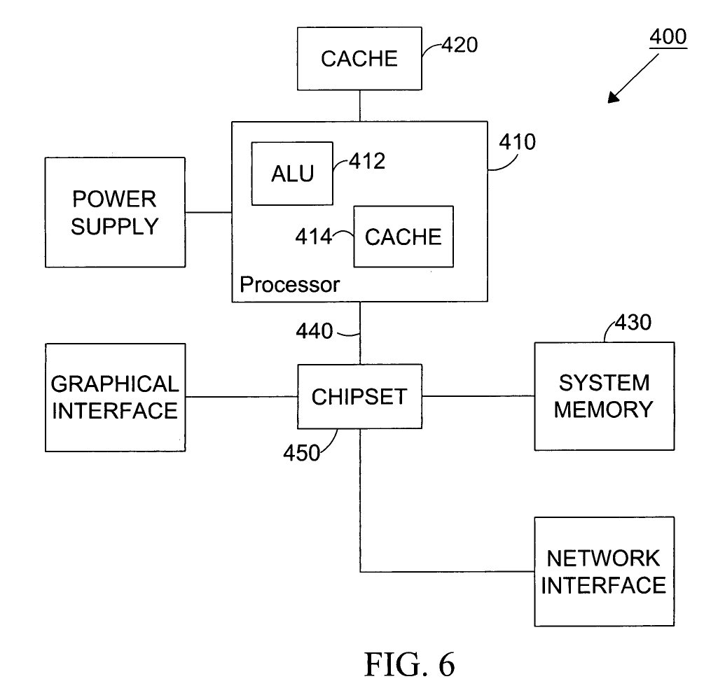

Embodiments of the present invention may be utilized after fabrication of a die using a testing device such as shown in FIG. 5. That is, FIG. 5 is a block diagram of a testing device or system according to an example embodiment of the present invention. Other embodiments and configurations are also within the scope of the present invention. More specifically, FIG. 5 shows a holding device 305, such as a socket, to receive a packaged die 310 such as during class testing. A testing device 320, such as a tester, may be connected to the holding device 305 so as to receive information and provide information relative to the die 310. For example, the testing device 320 may include a thermal controller 322 to set a temperature of the die 310, a memory 324 and a processor 326. Although not shown, the memory 324 and the processor 326 may be provided external to (or separate from) the actual testing device 320. The memory 324 may store test vector and other relevant information for the testing and the processor 326 may include the capability to run the various tests, check output values for correctness and other processes. The testing device 320 may also include a wireless interface 328 to communicate data to other devices such as a computer system as shown in FIG. 6.

In another example embodiment of the present invention, testing may be performed at a wafer sort. In this embodiment, the testing device may include probes to contact the die and allow the various testing based on information within the processor or memory.

Various features described above may be implemented in a computer program. As such, these features may be stored on a storage medium having stored thereof instructions which can be used to program a computer system to perform embodiments of the present invention. The storage medium may include, but is not limited to, any type of disk including floppy disks, optical disks, compact disk read-only memories (CD-ROMs), compact disc rewritables (CD-RWs), and magneto-optical disks, semiconductor devices such as read-only memories (ROMs), random access memories (RAMs), erasable programmable read-only memories (EPROMs), electrically erasable programmable read-only memories (EEPROMs), magnetic or optical cards, or any type of media suitable for storing electronic instructions. Similarly, features may be implemented as software modules executed by a programmable control device. A programmable control device may be a computer processor or a custom designed state machine. Custom designed state machines may be embodied in a hardware device such as a printed circuit board having discrete logic, integrated circuits, or specially designed application specific integrated circuits (ASICs).

FIG. 6 is a block diagram of a system (such as a computer system 400) according to an example embodiment of the present invention. Other embodiments and configurations are also within the scope of the present invention. More specifically, the computer system 400 may include a processor 410 that may have many sub-blocks such as an arithmetic logic unit (ALU) 412 and an on-die (or internal) cache 414. The processor 410 may also communicate to other levels of cache, such as off-die cache 420. Higher memory hierarchy levels such as a system memory 430, such as RAM, may be accessed via a host bus 440 and a chip set 450. The system memory 430 may also be accessed in other ways, such as directly from the processor 410 and/or without passing through the host bus 440 and/or the chip set 450. In addition, other off-die functional units such as a graphics accelerator and a network interface controller, to name just a few, may communicate with the processor 410 via appropriate busses or ports. The system may also include a wireless interface to interface the system 400 with other systems, networks, and/or devices via a wireless connection.

Systems represented by the various foregoing figures can be of any type. Examples of represented systems include computers (e.g., desktops, laptops, handhelds, servers, tablets, web appliances, routers, etc.), wireless communications devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, When a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A method comprising:
measuring characteristics of a die at various combinations of power supply voltage and body bias voltage; and
determining a power supply voltage and body bias voltage based on the measured characteristics of the die.

2. The method of claim 1, wherein the determined characteristics optimize an operating frequency of the die.

3. The method of claim 1, wherein measuring the characteristics comprises:
applying a first power supply voltage;
applying a first body bias voltage; and
measuring a frequency of the die having the first power supply voltage and the first body bias voltage.

4. The method of claim 3, wherein measuring the characteristics further comprises storing the measured frequency.

5. The method of claim 3, wherein measuring the characteristics further comprises:
applying a second power supply voltage;
applying a second body bias voltage; and
measuring another frequency of the die having the second power supply voltage and the second body bias voltage.

6. The method of claim 5, wherein determining the power supply voltage and the body bias voltage is based on the measured frequency of the die having the first power supply voltage and the first body bias voltage as well as the measured frequency of the die having the second power supply voltage and the second body bias voltage.

7. The method of claim 1, further comprising operating the die at the determined power supply voltage and body bias voltage.

8. The method of claim 1, wherein measuring the characteristics comprises measuring one of power and/or frequency of the die at various combinations of power supply voltage, body bias voltages and temperature.

9. The method of claim 1, wherein measuring the characteristics comprises:
applying a first power supply voltage;
maintaining a first relatively constant temperature;
applying a first body bias voltage; and
measuring a frequency of the die having the first power supply voltage, the first body bias and the first maintained relatively constant temperature.

10. The method of claim 9, wherein measuring the characteristics further comprises:
maintaining a second relatively constant temperature;
applying a second power supply voltage;
applying a second body bias voltage; and
measuring another frequency of the die having the second power supply voltage, the second body bias and the second maintained relatively constant temperature.

11. The method of claim 10, further comprising operating the die at the determined power supply voltage and body bias voltage.

12. A method comprising:
determining a first operating frequency based on a first power supply voltage and a first body bias voltage;
determining a second operating frequency based on a second power supply voltage and a second body bias voltage; and
determining an operating power supply voltage and body bias voltage based at least on the determined first operating frequency and the determined second operating frequency.

13. The method of claim 12, wherein the determined operating power supply voltage and determined body bias voltage optimize an operating frequency of a die.

14. The method of claim 12, further comprising operating transistors at the determined operating power supply voltage and the determined body bias voltage.

15. The method of claim 12, wherein determining the first operating frequency is further based on a first temperature and determining the second operating frequency is further based on a second temperature.

16. The method of claim 12, wherein determining the first operating frequency and determining the second operating frequency are performed at a same temperature, and the method further includes determining a third operating frequency based on the first power supply voltage, the first body bias voltage and a second temperature.

17. An apparatus comprising:
a holding device to receive a fabricated die; and
a testing device to couple the holding device or the die, the testing device to determine a power supply voltage and a body bias voltage for the die based on measured characteristics of the die received in the holding device.

18. The apparatus of claim 17, wherein the testing device measures characteristics of the die at various combinations of the power supply voltage and the body bias voltage.

19. The apparatus of claim 17, wherein the testing device measures the characteristics by applying a first power supply voltage, applying a first body bias voltage and measuring a frequency of the die having the first power supply voltage and the first body bias voltage.

20. The apparatus of claim 19, wherein the testing device determines the power supply voltage and the body bias voltage based on the measured frequency of the die having the first power supply voltage and the first body bias voltage as well as a measured frequency of the die having a second power supply voltage and a second body bias voltage.

21. The apparatus of claim 17, wherein the testing device measures one of power and/or frequency of the die at various combinations of power supply voltage, body bias voltages and temperature.

22. A system comprising:
a wireless interface to communicate with a device;
a holding device to support a die under test; and
a testing device to test characteristics of dies at a plurality of different power supply and body bias conditions and to select an operating supply voltage and body bias voltage based on the tested characteristics.

23. The system of claim 22, wherein the testing device tests characteristics by measuring one of power and/or frequency of a die at various combinations of power supply voltage, body bias voltage and temperature.

24. The system of claim 22, wherein the testing device selects the operating power supply voltage and the body bias voltage based on a measured frequency at a first power supply voltage and a first body bias voltage as well as a measured frequency at a second power supply voltage and a second body bias voltage.
